(19) United States
(12) Patent Application Publication
(10) Pub. No.: US 2013/0327387 A1
(43) Pub. Date: Dec. 12, 2013

(54) Se OR S BASED THIN FILM SOLAR CELL AND METHOD FOR FABRICATING THE SAME

(71) Applicant: KOREA INSTITUTE OF SCIENCE AND TECHNOLOGY, Seoul (KR)

(72) Inventors: Won Mok KIM, Seoul (KR); Jin Soo KIM, Seoul (KR); Jeung Hyun JEONG, Seoul (KR); Young Joon BAIK, Seoul (KR); Jong Keuk PARK, Seoul (KR)

(73) Assignee: KOREA INSTITUTE OF SCIENCE AND TECHNOLOGY, Seoul (KR)

(21) Appl. No.: 13/729,275

(22) Filed: Dec. 28, 2012

(30) Foreign Application Priority Data
Jun. 8, 2012 (KR) 10-2012-0061357

(51) Int. Cl. H01L 31/0224; H01L 31/18

(52) U.S. Cl. CPC H01L 31/022483; H01L 31/1884
USPC 136/256; 438/95

(57) ABSTRACT

The present disclosure relates to a Se or S based thin film solar cell and a method for fabricating the same, which may improve crystallinity and electric characteristics of an upper transparent electrode layer (6) by controlling a structure of a lower transparent electrode layer (5′) in a thin film solar cell having a Se or S based light absorption layer. In the Se or S based thin film solar cell according to the present disclosure, the front transparent electrode layer comprises a lower transparent electrode layer (5′) and an upper transparent electrode layer (6), and the lower transparent electrode layer (5′) comprises an amorphous oxide-based thin film.

### CROSS-REFERENCE TO RELATED APPLICATION

This application claims priority to Korean Patent Application No.10-2012-0061357, filed on Jun. 18, 2012, and all the benefits accruing therefrom under 35 U.S.C. §119, the contents of which in its entirety are herein incorporated by reference.

### BACKGROUND

1. Field

The present disclosure relates to a Se or S based thin film solar cell and a method for fabricating the same, and more particularly, to a Se or S based thin film solar cell and a method for fabricating the same, which may improve crystallinity and electric characteristics of an upper transparent electrode layer by controlling a structure of a lower transparent electrode layer in a thin film solar cell having a Se or S based light absorption layer.

2. Description of the Related Art

A Se or S based thin film solar cell such as GIGS (Cu(In₁₋ₓGaₓ)(Se,S)₂) and CZTS (Cu₂ZnSn(Se,S)₄) is expected as a next-generation inexpensive high-efficient solar cell since it may exhibit high photoelectric transformation efficiency due to a high light absorption rate and excellent semiconductor characteristics (a GIGS solar cell exhibits photoelectric transformation efficiency of 20.3%—ZSW in German). Since the GIGS solar cell may be used as a high-efficient solar cell even on not only a transparent glass substrate but also a metal substrate made of stainless steel, titanium or the like and a flexible substrate such as a polyimide (PI) substrate, the GIGS solar cell may be produced at a low cost by means of a roll-to-roll process, may be installed at a low cost due to light weight and excellent durability, and may be applied in various fields as BIPV and various portable energy sources due to its flexibility.

FIG. 1 shows a most universal structure of a thin film solar cell 1 having a Se or S based light absorption layer. An opaque metal electrode layer 2 is provided on a substrate 1, a Se or S based p-type light absorption layer 3 is provided on the opaque metal electrode layer 2, and a sulfide-based n-type buffer layer 4 made of CdS or ZnS is provided on the light absorption layer 3. Front transparent electrode layers 5, 6 are provided on the buffer layer 4, and the front transparent electrode layers 5, 6 play a role of transmitting solar rays as much as possible so that the solar rays reaches the light absorption layer and a function of collecting and taking out carriers generated by the solar rays absorbed by the light absorption layer. In other words, front transparent electrode layers 5, 6 should have excellent transmission property with respect to visible rays and light in a near-infrared region and excellent electric conductivity.

Generally, in the thin film solar cell having a Se or S based light absorption layer, the front transparent electrode layers 5, 6 have a double-layer structure composed of a lower transparent electrode layer 5 and an upper transparent electrode layer 6 (U.S. Pat. No. 5,078,804 and US Unexamined Patent Publication No. 2005-109392). The lower transparent electrode layer 5 has semiconductor characteristics, but due to very high electric resistivity, its necessity and role are still controversial. However, it has been reported that the lower transparent electrode layer 5 contributes to stability of a solar cell and enhances reproducibility in fabricating a module. This is because, in the case the upper transparent electrode layer 6 which is highly conductive due to large doping comes in direct contact with a buffer layer, the influence of defects such as a pin-hole probably existing in the light absorption layer increases, and the non-uniformity in the electric field of the upper transparent electrode layer 6 may cause local irregularity of the solar cell. Accordingly, in the thin film solar cell having a Se or S based light absorption layer presently used in the art, intrinsic ZnO (i-ZnO) with a relatively high electric resistance is formed on the buffer layer 4 as the lower transparent electrode layer 5. In addition, n-type ZnO doped with impurity elements such as Al, Ga, B, F, and H is used on the lower transparent electrode layer 5 as the upper transparent electrode layer 6 (NREL internal report NREL/CP-520-46235, I. Repins, et al.). In other words, the double layer of i-ZnO/n-type ZnO is used as the front transparent electrode layers 5, 6.

### RELATED LITERATURES

### Patent Literature

U.S. Pat. No. 5,078,804

US Unexamined Patent Publication No. 2005-109392

### Non-Patent Literature

NREL internal report NREL/CP-520-46235, I. Repins, et al.

### SUMMARY

A ZnO-based oxide thin film used as a front transparent electrode layer is generally deposited by means of sputtering or chemical vapor deposition (CVD), and the sputtering method is most frequently used due to easiness in treatment of a large area and excellent electric characteristics.

The doped ZnO-based transparent conductive oxide thin film is known to have improved conductivity if a deposition temperature rises since the crystallinity and doping efficiency of the thin film are improved, similar to a general thin film. However, this is just a case of an optimized doping composition, and different tendencies may be exhibited with different compositions.

FIG. 2 shows the change of specific resistivity according to a deposition temperature in an Al-doped ZnO thin film (hereinafter, referred to as AZO, see ‘2-1’ in FIG. 2) with an optimized doping amount and a Ga-doped ZnO thin film (hereinafter, referred to as GZO, see ‘2-2’ in FIG. 2). When the deposition temperature is low, the thin films exhibit deteriorated crystallinity and possess many defects, resulting in films with relatively high specific resistivity. The films deposited at temperature near 150° C. exhibited the lowest specific resistivity. With further increase in deposition temperature, the specific resistivity increased. The increase in the specific resistivity for films deposited at higher temperature is attributed to two reasons; (1) the formation of large amount of defects in ZnO may be probable due to the loss of Zn with high equilibrium vapor pressure, or (2) Al or Ga dopants may forms oxide in the form of Al—O or Ga—O instead of serving as a doping element in Zn sites, which will cause the lowering of the carrier concentration and Hall mobility. In FIG. 2, it may be found that the AZO 2-1 and the GZO 2-2 have most excellent electric characteristics near 150° C. Even in a ZnO-based thin film with an optimized doping amount, it is obvious that the temperature exhibiting optimized electric characteristics may vary according to a deposition method or a deposition condition.

In the case of the Ga-doped ZnO thin films 2-3 and 2-4 having a doping amount less than the optimized doping amount, as the deposition temperature rises, the specific resistivity decreases. However, in the thin film solar cell having a Se or S based light absorption layer, it is not favorable for the deposition temperature of the front transparent electrode layer to exceed the range of 150 to 200° C. Therefore, in the thin film solar cell having a Se or S based light absorption layer, it can be seenthat the condition for forming a front transparent electrode layer with optimized electric characteristics is fabricating a ZnO thin film with an optimized doping composition at deposition temperature range from 150 to 200° C.

FIG. 3 shows the variations of specific resistivities of GZO films deposited at room temperature (3-1 and 3-2) and 150° C. (3-3 and 3-4) as a function of the thickness of the lower transparent electrode layer made of intrinsic ZnO (i-ZnO). The GZO films 3-1 and 3-3 are deposited directly on glass substrates, and the GZO films 3-2 and 3-4 are deposited on i-ZnO layer pre-coated on glass substrates using identical deposition condition to 3-1 and 3-3, respectively. First, if comparing the results at room temperature, the GZO thin film 3-1 deposited directly on the glass substrate and the GZO thin film 3-2 deposited on the i-ZnO layer exhibit very similar specific resistivity except for the case of the thickest i-ZnO layer. In the case of the thickest i-ZnO layer, the GZO thin film 3-2 deposited on the i-ZnO layer has specific resistivity slightly lower than the GZO thin film 3-1 deposited on the glass substrate. However, when the deposition is carried out at 150° C., it may be found that the specific resistivities of the GZO thin films 3-3 on the glass substrate are lower than those of the GZO thin film 3-4 deposited on the i-ZnO layer of any thickness. In addition, it may also be understood that, as the thickness of the i-ZnO layer increases, the specific resistivity of the GZO thin film deposited thereon increases.

FIG. 4 shows the variations of Hall mobilities for the corresponding thin films shown in FIG. 3. In case of room temperature deposition, it can be seen that GZO thin films 4-1 deposited on the glass substrates and GZO thin films 4-2 deposited on i-ZnO layers have very similar Hall mobility. However, in case of deposition at 150° C., it may be found that GZO thin films 4-3 deposited on the glass substrate exhibit significantly higher Hall mobility than GZO thin films 4-4 deposited on the i-ZnO, and the difference increases as the thickness of i-ZnO increases.

Referring to the results of FIGS. 3 and 4, it can be seen that the doped ZnO thin films, which have optimized electrical properties, deposited on i-ZnO layer at 150 to 200° C. exhibit lower Hall mobility and higher specific resistivity than those deposited on the glass substrates at the corresponding deposition temperature.

The ZnO-based thin films generally have a hexagonal wurtzite structure. When deposited by sputtering, the films grow along a preferred orientation with (0002) surface parallel to the substrate surface, frequently revealing strong (0002) peak at around 34.4 degree in X-ray diffraction spectrum. In FIG. 5, the (0002) peaks from the X-ray diffraction spectra of the GZO thin films deposited on 46 nm thick i-ZnO layers at room temperature and 150° C. are compared with those of GZO films deposited on the glass substrates at corresponding temperatures. Referring to FIG. 5, in case of room temperature deposition, it can be seen that the X-ray diffraction peak of a GZO thin film 5-2 deposited on the i-ZnO layer is only slightly smaller than that of a GZO thin film 5-1 deposited on the glass substrate. In case of the deposition at 150° C., the GZO thin film 5-3 deposited on the glass substrate exhibits a very large (0002) peak intensity, indicating that the film possesses well developed crystallinity. On the other hand, the (0002) peak intensity of the GZO thin film 5-4 deposited on the i-ZnO layer is not much different from those of the GZO thin films 5-1 and 5-2 deposited at room temperature, which shows that crystallinity of the GZO film deposited on i-ZnO layer is not improved in spite of being deposited at 150° C.

FIG. 6 shows the (0002) peaks of an i-ZnO layer 6-1 and a GZO thin film 6-2 deposited at 150° C. on the glass substrate. Both i-ZnO layer 6-1 and GZO thin film 6-2 have a thickness of around 95 nm. Clearly, the crystallinity of the GZO thin film 6-2 is far better than that of the i-ZnO layer 6-1. This is because the impurities doped in ZnO play a role of mineralizer or surfactant in promoting crystal growth. For this reason, if a doped ZnO thin film (for example, a GZO thin film) serving as an upper transparent electrode layer is grown on the i-ZnO layer serving as a lower transparent electrode layer with poor crystallinity, the crystallinity of the upper transparent electrode layer (the doped ZnO) is deteriorated due to the influence of bad crystallinity of the lower transparent electrode layer (i-ZnO) in comparison to the thin film grown on the glass substrate.

When the deposition temperature is low, atoms, molecules or ions sputtered from a target and deposited to the substrate do not have sufficient energy. The atoms, molecules or ions arriving at the substrate are mostly deposited at the locations reaching the substrate due to low ad-atom mobility. Therefore, the structure of the growing film is not affected by the structure of the underneath layer or the substrate. (for example, the glass substrate or i-ZnO) For this reason, the GZO thin films deposited on the glass substrate and i-ZnO layer at room temperature show almost similar structural characteristics (as shown in FIG. 5) and electrical characteristics (as shown in FIGS. 3 and 4) to each other. On the other hand, if the deposition is carried out at an elevated temperature, the thermal energy from the heated substrate provides the atoms, molecules or ions with sufficient ad-atom mobilities for reaching the substrate. Accordingly, the crystallinity of the growing thin film is significantly influenced by the structure of the underneath layer. Therefore, in case of deposition at 150° C., the crystallinity of the GZO thin film grown on the i-ZnO layer is deteriorated due to the poor crystallinity of i-ZnO layer in comparison to that of the GZO thin film grown on the glass substrate. As shown in FIGS. 3 and 4, the poor crystallinity resulted in the low Hall mobility and the high specific resistivity for the GZO films deposited on i-ZnO layer at 150° C. in comparison to GZO films deposited on the glass substrate.

From the results above, it may be concluded that sufficient effects are not obtained only by raising a deposition temperature commonly used for improving electric characteristics of an upper transparent electrode layer using a doped ZnO in the thin film solar cell having a Se or S based light absorption layer using i-ZnO as a lower transparent electrode layer.

The present disclosure is directed to providing a Se or S based thin film solar cell and a method for fabricating the same, which may improve crystallinity and electric characteristics of an upper transparent electrode layer by controlling a structure of a lower transparent electrode layer in a thin film solar cell having a Se or S based light absorption layer.

In one aspect, there is provided a Se or S based thin film solar cell having a light absorption layer and a front transparent electrode layer, wherein the front transparent electrode layer is composed of a lower transparent electrode layer and an upper transparent electrode layer, and wherein the lower transparent electrode layer is composed of an amorphous oxide-based thin films.

The amorphous oxide-based thin films may have a photonic band-gap of 3.0 to 4.2 eV. In addition, the amorphous oxide-based thin films may be composed of a single-component oxide semiconductor or mixtures of plural kinds of oxide semiconductors. The amorphous oxide-based thin films may be made of any one of oxides of Zn, In, Sn, Ti, Ga, Cd, Sb, and V or their mixtures, and among the elements of the mixture, the metal elements except for oxygen may have an atomic ratio of 80% or above.

The amorphous oxide-based thin films may be made of mixtures of plural kinds of oxide semiconductors, and a photonic band-gap may be controllable according to a composition of the plural kinds of oxide semiconductors. For example, the amorphous oxide-based thin films may be made of mixtures of Zn oxide and Sn oxide, and the photonic band-gap may increase as the composition ratio of Sn increases. In the mixture of Zn oxide and Sn oxide, among metal components except for oxygen, an atom ratio of Sn may be adjusted to 15 to 90 atom%.

The upper transparent electrode layer may be composed of a ZnO-based thin film.

In another aspect, there is also provided a method for fabricating a Se or S based thin film solar cell having a light absorption layer, a lower transparent electrode layer and an upper transparent electrode layer, the method including: forming a lower transparent electrode layer composed of an amorphous oxide-based thin film; and forming a crystalline oxide-based thin film on the lower transparent electrode layer.

The Se or S based thin film solar cell and method for fabricating the same according to the present disclosure give the following effects.

Since the amorphous oxide-based thin film is used as the lower transparent electrode layer, the crystallinity of the upper transparent electrode layer may be enhanced, and accordingly electric characteristics of the upper transparent electrode layer may be improved. In addition, since the light absorption in a short-wavelength region can be improved by increasing photonic band-gap in comparison to an existing i-ZnO layer, the photoelectric transformation efficiency of the thin film solar cell may be increased.

Moreover, the photonic band-gap may be controlled according to a composition of plural kinds of oxide semiconductors of the amorphous oxide-based thin film, and the absorption edge may be selectively adjusted.

### BRIEF DESCRIPTION OF THE DRAWINGS

The above and other aspects, features and advantages of the disclosed exemplary embodiments will be more apparent from the following detailed description taken in conjunction with the accompanying drawings in which:

FIG. 1 is a cross-sectional view showing a conventional Se or S based thin film solar cell;

FIG. 2 is a graph showing the change of specific resistivity according to a deposition temperature of an Al-doped ZnO thin film and a Ga-doped ZnO thin film;

FIG. 3 is a graph showing the variations of the specific resistivities of GZO thin films deposited on glass substrates and i-ZnO layers grown on glass substrates at room temperature and 150° C., where the specific resistivities are plotted as a function of the thickness of the i-ZnO layeri-ZnO layer;

FIG. 4 is a graph showing the corresponding variations in Hall mobilities of the GZO thin films shown in FIG. 3;

FIG. 5 shows X-ray diffraction analysis results of (0002) peak of GZO thin films deposited at room temperature and 150° C. in the case the i-ZnO layer has a thickness of about 46 nm in the results of FIGS. 3 and 4;

FIG. 6 shows X-ray diffraction analysis results of an i-ZnO layer 6-1 and a GZO thin film 6-2 with a similar thickness, which are deposited on the glass substrate at 150° C.;

FIG. 7 is a cross-sectional view showing a Se or S based thin film solar cell according to an embodiment of the present disclosure;

FIG. 8A shows X-ray diffraction analysis results of amorphous thin films made of mixtures of Zn oxide and Sn oxide, and FIG. 8B shows optical transmittance of the amorphous thin films made of mixtures of Zn oxide and Sn oxide;

FIG. 9 shows X-ray diffraction analysis results of GZO thin films (respectively) for the case where a GZO thin film is formed on a glass substrate (GZO/Glass) 9-1, and for the case where ZTO and GZO thin films are sequentially deposited on the glass substrate (GZO/ZTO/Glass) 9-2, and for the case where i-ZnO and GZO thin films are sequentially deposited on the glass substrate (GZO/i-ZnO/Glass) 9-3; and

FIG. 10 shows optical transmittance spectra of an i-ZnO layer 10-1, an AZO thin film 10-2 (deposited in excessive oxygen atmosphere), an AZO thin film 10-3 (deposited in pure Ar), and a ZTO thin film 10-4, respectively.

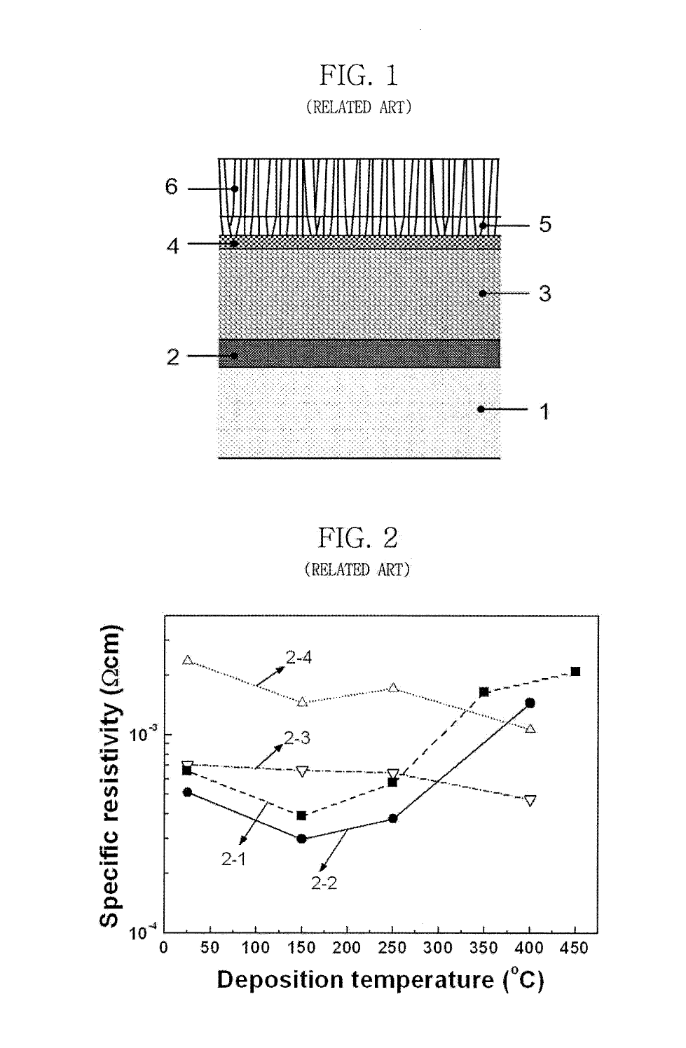

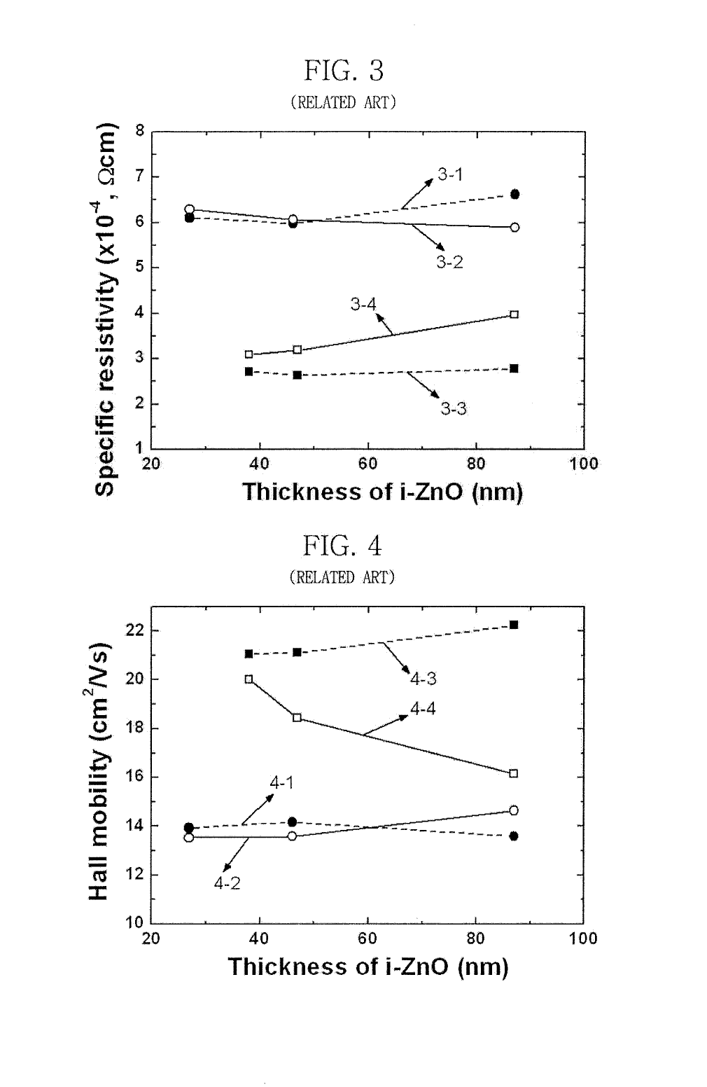

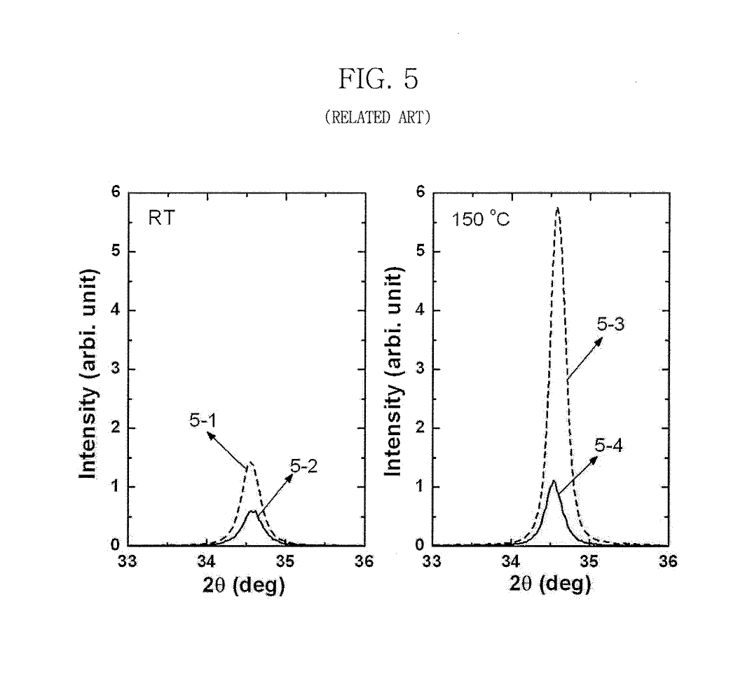

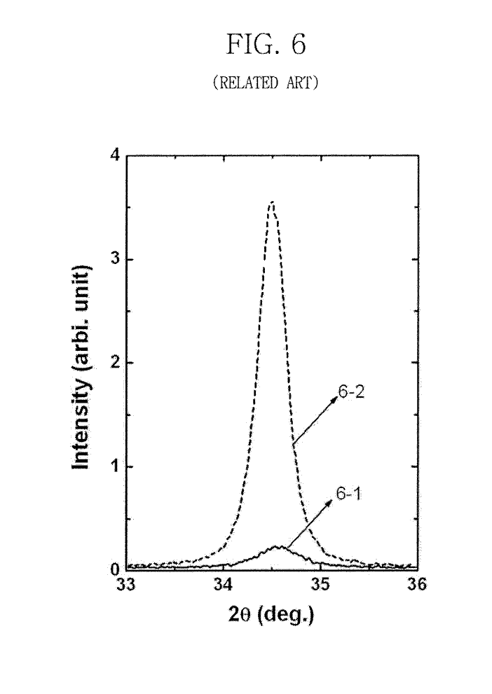

[Detailed Description of Main Elements]

| | |
|---|---|
| 1: substrate | 2: rear electrode |
| 3: light absorption layer | 4: buffer layer |

5′: amorphous lower transparent electrode layer
6: upper transparent electrode layer

### DETAILED DESCRIPTION

Exemplary embodiments now will be described more fully hereinafter with reference to the accompanying drawings, in which exemplary embodiments are shown.

The present disclosure relates to a front transparent electrode layer of a so-called Se or S based thin film solar cell, which uses Se or S based material as a light absorption layer.

The front transparent electrode layer may be implemented as a double-layer structure composed of an upper transparent electrode layer and a lower transparent electrode layer, and the upper transparent electrode layer plays a role of collecting carriers generated by photoelectric transformation.

In order to collect carriers efficiently, the upper transparent electrode layer uses a thin film doped with impurity elements, thereby accomplishing high electric resistivity. The lower transparent electrode layer is composed of an amorphous thin film with relatively high resistivity. In addition, in order to enhance light absorption, both the upper transparent electrode layer and the lower transparent electrode layer should have excellent light transparency.

In other words, the upper transparent electrode layer should have high transparency and low specific resistivity, and the lower transparent electrode layer should have high transparency and high specific resistivity. In order to satisfy these conditions, in the present disclosure, a crystalline oxide-based thin film doped with impurity elements and having excellent crystallinity is applied as the upper transparent electrode layer, and an amorphous oxide-based thin film is applied as the lower transparent electrode layer.

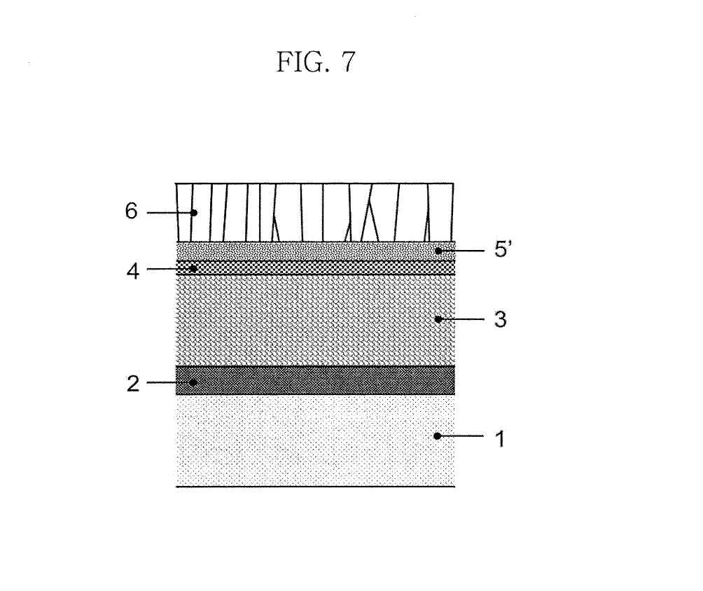

Looking into the overall configuration of the Se or S based thin film solar cell to which the upper transparent electrode layer 6 and the lower transparent electrode layer 5′ according to the present disclosure are applied (see FIG. 7), a rear electrode 2, a light absorption layer 3, a buffer layer 4, a lower transparent electrode layer 5′, and an upper transparent electrode layer 6 are sequentially laminated on a substrate 1. It is worth mentioning that components other than the lower transparent electrode layer 5′ and the upper transparent electrode layer 6 may be selectively modified if necessary. The rear electrode 2 is made of opaque metallic material such as molybdenum (Mo), the light absorption layer 3 is made of Se or S based material such as Cu(In₁₋ₓGaₓ)(Se,S)₂ (CIGS) and Cu₂ZnSn(Se,S)₄ (CZTS), and the buffer layer 4 may be made of material such as CdS and ZnS. In the Se or S based thin film solar cell as described above, the light absorption layer 3 and the buffer layer 4 make a p-n junction to induce photoelectric transformation, and carriers (electrons and holes) generated by the photoelectric transformation are respectively collected by a front transparent electrode layer and a rear electrode 2 to generate electricity.

In order to ensure high light transparency, restrain recombination of carriers and enhance carrier collecting efficiency, both the upper transparent electrode layer 6 and the lower transparent electrode layer 5′ should have a photonic band-gap over a certain level. In addition, as described above, the upper transparent electrode layer 6 should have low specific resistivity, and the lower transparent electrode layer 5′ should have relatively high specific resistivity.

In the present disclosure, an amorphous oxide-based thin film is applied as the lower transparent electrode layer 5′, and a crystalline oxide-based thin film doped with impurity elements is applied as the upper transparent electrode layer 6. The amorphous thin film is used as the lower transparent electrode layer 5′ in order to ensure crystallinity of the upper transparent electrode layer 6 over a certain level when the upper transparent electrode layer 6 is deposited.

In the case the ZnO-based thin film available as the upper transparent electrode layer 6 is grown on an amorphous substrate or thin film, nanocrystallite of the ZnO-based thin film is formed in an early stage on a growth surface. If the deposition proceeds further, crystal growth occurs in the direction of crystal face with fast growth speed according to the evolutionary selection rule, resulting in large crystallite with a preferred orientation and less defects. In this way, the upper transparent electrode layer 6 with excellent crystallinity may be formed, and the electric resistivity may be enhanced further by an appropriate doping. A ZnO thin film doped with at least one of Al, Ga, B, F, and H may be used as the upper transparent electrode layer 6.

In the present disclosure, the amorphous oxide-based thin film is applied as the lower transparent electrode layer 5′. The amorphous oxide-based thin film may be made of a single-component oxide or mixtures of two or more kinds of oxides, and may be an oxide semiconductor with a photonic band-gap of 3.0 to 4.2 eV. For example, the lower transparent electrode layer 5′ may be an amorphous oxide composed of any one of Zn, In, Sn, Ti, Ga, Cd, Sb, V, and their mixtures, and among the elements of the mixture, the metal elements other than oxygen may have an atomic ratio of 80% or above. If the photonic band-gap does not increase more highly than 3.0 eV, the light transparency characteristic of the amorphous oxide-based thin film in the visible region is deteriorated, and so the photonic band-gap equal to or larger than 3.0 eV may be preferred. In addition, in order to maintain semiconductor characteristics of the amorphous oxide-based thin film, the main metal elements other than oxygen may have an atomic ratio of 80% or above.

The amorphous oxide-based thin film may be formed by using a sputtering process. In case of using two or more kinds of oxides, the photonic band-gap may be selectively controlled by adjusting a composition ratio according to material characteristics. Referring to the examples of the present disclosure described later, in the case the mixture of Zn oxide and Sn oxide is used as the lower transparent electrode layer 5′, the photonic band-gap of the lower transparent electrode layer 5′ may be controlled in various ways by adjusting relative composition ratios of Zn and Sn. In case of using the mixture of Zn oxide and Sn oxide, as the composition ratio of Sn becomes larger, the photonic band-gap increases, and the optical transmittance of a short-wavelength region is improved. Both the upper transparent electrode layer 6 and the lower transparent electrode layer 5′ may be formed by sputtering or other types of vapor deposition techniques. The examples of the present disclosure described later use an amorphous oxide composed of Zn and Sn oxides. However, similar effects are also expected even though a small amount of other oxides such as Ga, In or other metal oxides are added in order to put a certain properties into the amorphous oxide-based thin film.

Hereinafter, the characteristics of the lower transparent electrode layer 5′ applied to the Se or S based thin film solar cell according to the present disclosure will be described by means of examples.

### EXAMPLE 1

Amorphous thin films made of mixtures of Zn oxide and Sn oxide were prepared, and their structural characteristics and optical transmittance characteristics were examined. By adjusting an atomic ratio of Sn among metal elements other than oxygen, ZTO films with Sn content of 89, 83, 66, 54, 36, and 26% were prepared.

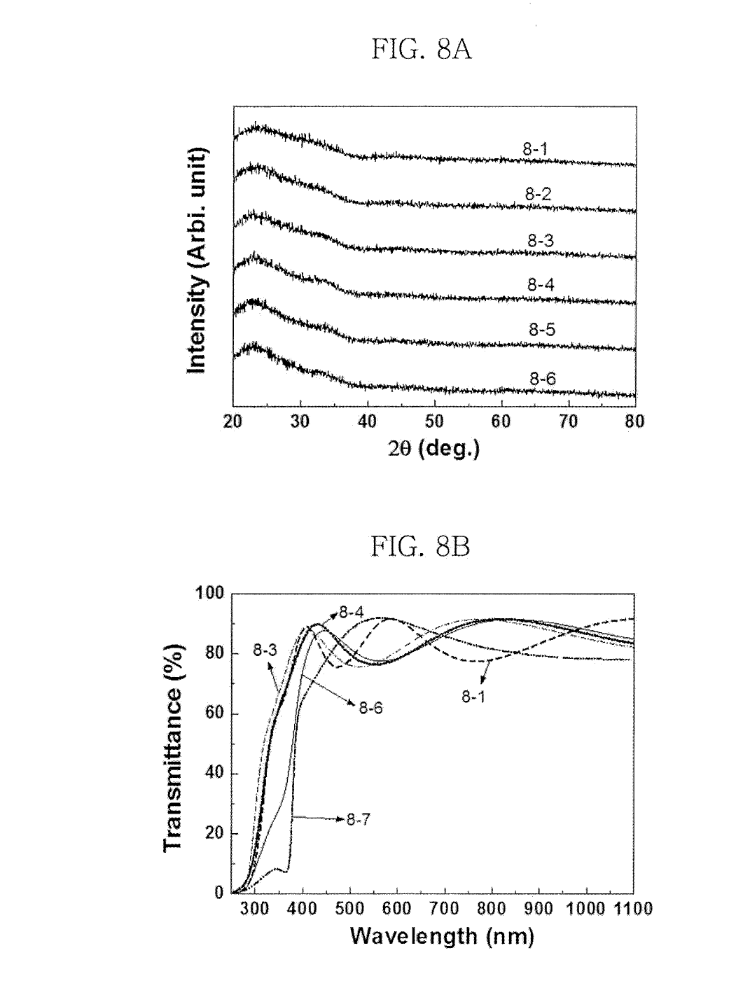

FIG. 8A shows X-ray diffraction spectra of the ZTO thin films. The reference numbers 8-1, 8-2, 8-3, 8-4, 8-5, and 8-6 represent that the amorphous thin film composition ratio of Sn 89, 83, 66, 54, 36, and 26 atom %, respectively. Clearly, no crystalline peak is observable, and it can be seen that these ZTO films show an amorphous structure in all compositions examined.

FIG. 8B shows the optical transmittance spectra of the amorphous ZTO thin films selected from FIG. 8A together with that of i-ZnO layer 8-7. In FIG. 8B, the optical transmittance abruptly decreases in the ultraviolet region. This region where the optical transmittance abruptly decreases indicates the absorption edge inherent to the material (a fundamental absorption edge) and may be expressed as a photonic band-gap.

Referring to FIG. 8B, it can be seen that the absorption edges of amorphous ZTO thin films of various compositions 8-1, 8-2, 8-3, 8-4, 8-5, 8-6 are positioned in a shorter wavelength region than the absorption edge of an i-ZnO layer 8-7, which means excellent transparency with respect to light in an ultraviolet region. The photonic band-gap increases as the absorption edge moves toward the short wavelength region. In other words, if an amorphous ZTO thin film is used as the lower transparent electrode layer 5′ instead of i-ZnO layer, the light absorption efficiency may be improved due to the enhanced absorption in ultraviolet region. In addition, in FIG. 8B, it can be seen that the absorption edge is moved toward the short-wavelength region as the composition ratio of Sn increases, and accordingly, it may be checked that the photonic band-gap may be controlled by adjusting the composition ratios of Zn oxide and Sn oxide.

### EXAMPLE 2

The amorphous ZTO thin film as mentioned in Example 1 was used as the lower transparent electrode layer 5′, and a GZO thin film (a Ga-doped ZnO thin film) was deposited on the ZTO thin film. For this case, X-ray diffraction analysis was performed.

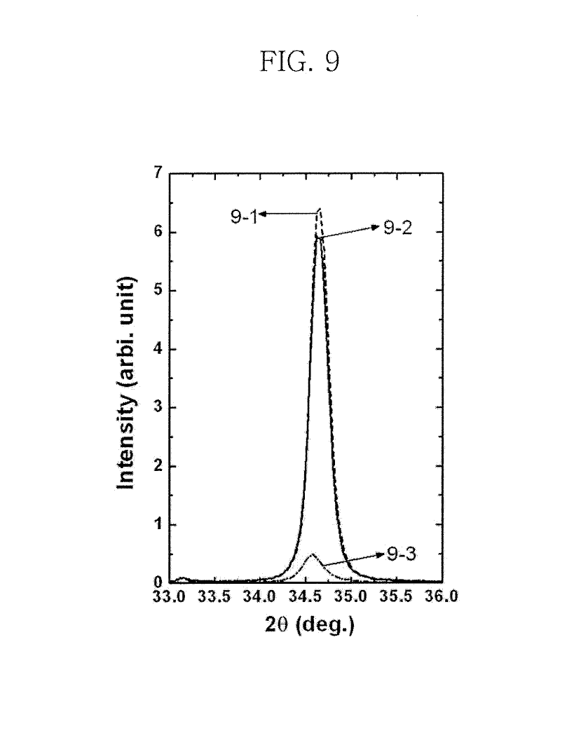

FIG. 9 compares (shows) the X-ray diffraction spectrum (analysis results) of a GZO thin film deposited on ZTO layer grown on a glass substrate (GZO/ZTO/Glass) 9-2 with those of the GZO thin films deposited on directly the glass substrate (GZO/Glass) 9-1- and on i-ZnO layer grown on the glass substrate (GZO/i-ZnO/Glass) 9-3.

Referring to FIG. 9, the GZO/ZTO/Glass 9-2 and the GZO/ Glass 9-1 show (0002) peaks with substantially identical sizes, but the GZO/i-ZnO/Glass 9-3 shows a very small (0002) peak. From this result, if the amorphous lower transparent electrode layer 5′ according to the present disclosure is used, the upper transparent electrode layer 6 may obtain crystallinity over a certain level, namely crystallinity corresponding to the thin film layer formed on the glass substrate.

Table 1 below shows specific resistivity, Hall mobility, and carrier concentration of the GZO/Glass 9-1, the GZO/ZTO/Glass 9-2, and the GZO/i-ZnO/Glass 9-3, respectively.

TABLE 1
Comparison of Electric Properties of each Thin Film Structure

| | specific resistivity | Hall mobility | carrier concentration |
|---|---|---|---|
| | (Ω cm) | (cm²/Vs) | (cm⁻³) |
| GZO/Glass | 3.04 × 10⁻⁴ | 20.5 | 1.01 × 10²¹ |
| GZO/ZTO/Glass | 2.94 × 10⁻⁴ | 22.9 | 9.3 × 10²¹ |
| GZO/i-ZnO/Glass | 4.22 × 10⁻⁴ | 15.9 | 9.3 × 10²⁰ |

Referring to Table 1, the specific resistivity of the GZO/ZTO/Glass 9-2 is 2.94×10⁻⁴ Ωcm, which is substantially equivalent to or improved over 3.04×10⁻⁴ Ωcm of the GZO/Glass 9-1. The GZO/i-ZnO/Glass 9-3 shows high specific resistivity of 4.22×10⁻⁴ Ωcm. Such a difference in specific resistivity clearly shows that it originates from the decrease of Hall mobility caused by the difference in crystallinity of the GZO thin film as shown in FIG. 9.

### EXAMPLE 3

The optical transmittance characteristics of the ZTO thin film according to the present disclosure were compared with those of the i-ZnO layer and the AZO thin film (Al-doped ZnO thin film). US Unexamined Patent Publication No. 2009-14065 suggests a configuration where an AZO thin film is used as the upper transparent electrode layer 6 and the lower transparent electrode layer 5′. In detail, US Unexamined Patent Publication No. 2009-14065 applies an AZO thin film, which is formed by using Ar gas containing excessive oxygen as a sputtering gas and has relatively low electric resistivity, as the lower transparent electrode layer 5′ and applies an AZO thin film, which is formed by using Ar gas not containing oxygen or containing a small amount of oxygen as a sputtering gas and has relatively high electric resistivity, as the upper transparent electrode layer 6.

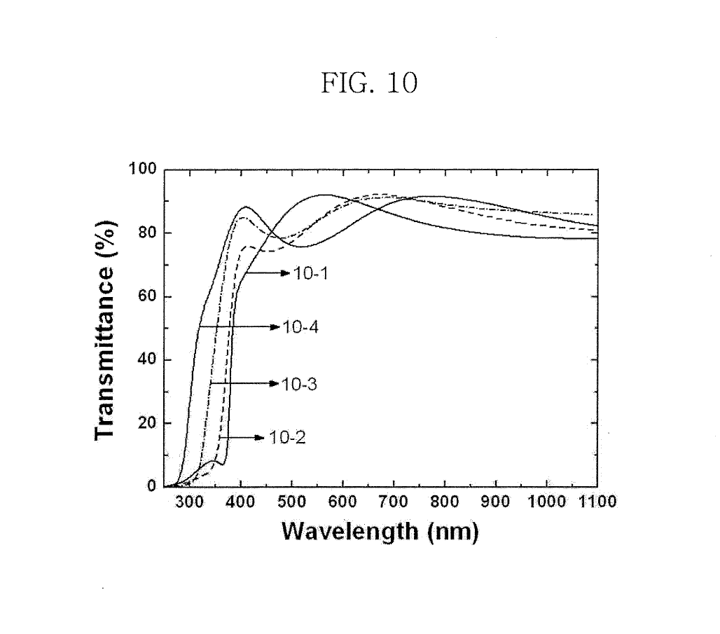

FIG. 10 shows optical transmittance of an i-ZnO layer 10-1, an AZO thin film (excessive oxygen) 10-2, an AZO thin film (pure Ar) 10-3, and a ZTO thin film 10-4, respectively. Referring to FIG. 10, it may be checked that the absorption edge of the i-ZnO layer 10-1 is located at the longest wavelength, and the absorption edge gradually moves toward the short wavelength in the order of the AZO thin film (excessive oxygen) 10-2, the AZO thin film (pure Ar) 10-3, and the ZTO thin film 10-4. As a result, if the amorphous ZTO thin film of the present disclosure is applied as the lower transparent electrode layer 5′, a higher photonic band-gap may be obtained in comparison to an existing i-ZnO layer or AZO thin film, and by doing so, the photoelectric transformation efficiency in the short wavelength region may be improved. For reference, it is known that, in case of a ZnO-based thin film doped with impurities, if the carrier concentration increases due to the doping of impurities, the photonic band-gap gradually moves toward the short wavelength due to the Burnstein-Moss shift, which is known as a band-filling effect. Therefore, the absorption edge of the AZO thin film (pure Ar) 10-3 is located at shorter wavelength than that of the AZO thin film (excessive oxygen) 10-2. In other words, even for the ZnO-based thin film doped with impurities, the absorption edge comes closer to the i-ZnO if deposition is performed under an Ar gas circumstance containing excessive oxygen in order to lower the electric resistivity.

While the exemplary embodiments have been shown and described, it will be understood by those skilled in the art that various changes in form and details may be made thereto without departing from the spirit and scope of the present disclosure as defined by the appended claims.

What is claimed is:

1. A Se or S based thin film solar cell having a light absorption layer and a front transparent electrode layer,
wherein the front transparent electrode layer comprises a lower transparent electrode layer (5′) and an upper transparent electrode layer (6), and
wherein the lower transparent electrode layer (5′) comprises an amorphous oxide-based thin film.

2. The Se or S based thin film solar cell according to claim 1, wherein the amorphous oxide-based thin film has a photonic band-gap of 3.0 to 4.2 eV.

3. The Se or S based thin film solar cell according to claim 1, wherein the amorphous oxide-based thin film comprises a single-component oxide semiconductor or mixtures of plural kinds of oxide semiconductors.

4. The Se or S based thin film solar cell according to claim 1, wherein the amorphous intrinsic oxide-based thin film comprises any one of oxides of Zn, In, Sn, Ti, Ga, Cd, Sb, and V or their mixtures, and among the elements of the mixture, the metal elements except for oxygen have an atomic ratio of 80% or above.

5. The Se or S based thin film solar cell according to claim 1, wherein the amorphous oxide-based thin film comprises mixtures of plural kinds of oxide semiconductors, and a photonic band-gap is controllable according to a composition of the plural kinds of oxide semiconductors.

6. The Se or S based thin film solar cell according to claim 1, wherein the amorphous oxide-based thin film comprises mixtures of Zn oxide and Sn oxide, and a photonic band-gap increases as a composition ratio of Sn increases.

7. The Se or S based thin film solar cell according to claim 6, wherein, in the mixture of Zn oxide and Sn oxide, an atomic ratio of Sn among metal elements except for oxygen is adjusted from 15 to 90 atom %.

8. The Se or S based thin film solar cell according to claim 1, wherein the upper transparent electrode layer (6) is made of a ZnO-based thin film.

9. A method for fabricating a Se or S based thin film solar cell having a light absorption layer, a lower transparent electrode layer (5′) and an upper transparent electrode layer (6), the method comprising:
forming a lower transparent electrode layer (5′) comprising an amorphous oxide-based thin film; and
forming a crystalline oxide-based thin film on the lower transparent electrode layer (5′).

10. The method for fabricating a Se or S based thin film solar cell according to claim 9, wherein the amorphous oxide-based thin film has a photonic band-gap of 3.0 to 4.2 eV.

11. The method for fabricating a Se or S based thin film solar cell according to claim 9, wherein the amorphous oxide-based thin film comprises a single-component oxide semiconductor or mixtures of plural kinds of oxide semiconductors.

12. The method for fabricating a Se or S based thin film solar cell according to claim 9, wherein the amorphous intrinsic oxide-based thin film comprises any one of oxides of Zn, In, Sn, Ti, Ga, Cd, Sb, and V or their mixtures, and among the elements of the mixture, the metal elements except for oxygen have an atomic ratio of 80% or above.

13. The method for fabricating a Se or S based thin film solar cell according to claim 9, wherein the amorphous oxide-based thin film comprises mixtures of plural kinds of oxide semiconductors, and a photonic band-gap is controllable according to a composition of the plural kinds of oxide semiconductors.

14. The method for fabricating a Se or S based thin film solar cell according to claim 9, wherein the amorphous oxide-based thin film comprises mixtures of Zn oxide and Sn oxide, and a photonic band-gap increases as a composition ratio of Sn increases.

15. The method for fabricating a Se or S based thin film solar cell according to claim 14, wherein, in the mixtures of Zn oxide and Sn oxide, an atomic ratio of Sn among metal elements except for oxygen is adjusted from 15 to 90 atom %.

16. The method for fabricating a Se or S based thin film solar cell according to claim 9, wherein the upper transparent electrode layer (6) comprises a ZnO-based thin film.
